(19) United States
(12) Patent Application Publication
(10) Pub. No.: US 2022/0283673 A1
(43) Pub. Date: Sep. 8, 2022

(54) Array Substrate and Preparation Method thereof, and Touch Display Apparatus

(71) Applicants: Hefei BOE Optoelectronics Technology Co., Ltd., Hefei (CN); BOE Technology Group Co., Ltd., Beijing (CN)

(72) Inventors: Dong WANG, Beijing (CN); Hongmin LI, Beijing (CN); Ying WANG, Beijing (CN)

(21) Appl. No.: 17/510,396

(22) Filed: Oct. 26, 2021

(30) Foreign Application Priority Data
Mar. 5, 2021 (CN) 202110244928.4

(51) Int. Cl. G06F 3/044; G06F 3/041; G02F 1/1333; G02F 1/1362; G02F 1/1368

(52) U.S. Cl. CPC G06F 3/0446; G06F 3/0412; G06F 3/04166; G02F 1/13338; G02F 1/136295; G02F 1/1368; G06F 2203/04103

(57) ABSTRACT

Provided is an array substrate including: a base substrate, a plurality of pixel units and a plurality of touch signal lines that are arranged on the base substrate. At least one pixel unit includes a plurality of sub-pixels. Two touch signal lines are arranged in the pixel unit, and the two touch signal lines are located on a side of a data line connected with one sub-pixel of the pixel unit.

### CROSS-REFERENCE TO RELATED APPLICATION

The present application claims priority to Chinese Patent Application No. 202110244928.4 filed to the CNIPA on Mar. 5, 2021, the content of which is incorporated herein by reference.

### TECHNICAL FIELD

Embodiments of the present disclosure relate to, but are not limited to, the field of display technology, in particular to an array substrate and a preparation method thereof, and a touch display apparatus.

### BACKGROUND

Touch screens are everywhere around us. The touch screen saves space and is convenient to carry, and has better human-computer interaction performance. Among multiple types of touch screens, a capacitive touch screen has advantages such as strong sensitivity and multi-point touch, and is widely used. In order to reduce a thickness of a panel, an In-cell touch structure has attracted wide attention. The In-cell touch structure includes two modes: a self-capacitance touch mode and a mutual-capacitance touch mode. An In cell touch screen has a higher integration and is lighter and thinner, so it has a wide application prospect.

### SUMMARY

The following is a summary of subject matters described in the present disclosure in detail. The summary is not intended to limit the scope of protection of the claims.

Embodiments of the present disclosure provide an array substrate and a preparation method thereof, and a touch display apparatus.

In one aspect, an embodiment of the present disclosure provides an array substrate, which includes a base substrate, a plurality of pixel units and a plurality of touch signal lines that are arranged on the base substrate. At least one pixel unit includes a plurality of sub-pixels; two touch signal lines are arranged in the pixel unit, and the two touch signal lines are located on a side of a data line connected with one sub-pixel of the pixel unit.

In some exemplary embodiments, the pixel unit includes a first sub-pixel, a second sub-pixel, and a third sub-pixel arranged sequentially; and two touch signal lines arranged in the pixel unit are located on a side of a data line connected with the first sub-pixel of the pixel unit.

In some exemplary embodiments, the plurality of touch signal lines and the plurality of data lines are structures in a same layer, and the plurality of touch signal lines extend along an extension direction of the plurality of data lines.

In some exemplary embodiments, the array substrate further includes a first transparent conductive layer and a second transparent conductive layer; and the second transparent conductive layer is located on a side of the first transparent conductive layer away from the base substrate. The first transparent conductive layer includes a plurality of common electrodes, and the second transparent conductive layer includes a plurality of pixel electrodes; or, the first transparent conductive layer includes a plurality of pixel electrodes, and the second transparent conductive layer includes a plurality of common electrodes. The common electrodes are reused as touch electrodes and connected with the touch signal lines.

In some exemplary embodiments, common electrodes of the plurality of sub-pixels of the pixel unit are of an integrated structure, and common electrodes of adjacent pixel units are connected through a first connection unit.

In some exemplary embodiments, overlapping areas of pixel electrodes of the plurality of sub-pixels of the pixel unit and corresponding common electrodes are approximately the same.

In some exemplary embodiments, an orthographic projection of the common electrode on the base substrate covers an orthographic projection of the data line on the base substrate.

In some exemplary embodiments, orthographic projections of the common electrodes on the base substrate are not overlapped with orthographic projections of the touch signal lines on the base substrate.

In some exemplary embodiments, the first transparent conductive layer and the second transparent conductive layer are both located on a side of the plurality of touch signal lines away from the base substrate.

In some exemplary embodiments, in a plane perpendicular to an array substrate, the array substrate at least includes a base substrate, and a first conductive layer, a semiconductor layer, a second conductive layer, a first transparent conductive layer, and a second transparent conductive layer that are disposed on the base substrate. The first conductive layer at least includes control electrodes of a plurality of switching elements and a plurality of gate lines; the semiconductor layer at least includes: active layers of a plurality of switching elements; the second conductive layer at least includes first and second electrodes of a plurality of switching elements, a plurality of data lines, and a plurality of touch signal lines. An organic insulating layer is arranged between the second conductive layer and the first transparent conductive layer.

In some exemplary embodiments, at least one switching element is located at an intersection position of a data line and a gate line.

In some exemplary embodiments, the first transparent conductive layer is located on a side of the plurality of touch signal lines close to the base substrate, and the second transparent conductive layer is located on a side of the plurality of touch signal lines away from the base substrate; the first transparent conductive layer includes a plurality of pixel electrodes, and the second transparent conductive layer includes a plurality of common electrodes.

In some exemplary embodiments, the plurality of sub-pixels of the plurality of pixel units form a plurality of columns of sub-pixels; and the two touch signal lines are located on a side of sub-pixels of a corresponding column.

In some exemplary embodiments, the data line is connected with sub-pixels of a corresponding column through switching elements, and the two touch signal lines are located on a side of a corresponding data line away from switching elements connected to the corresponding data line.

In another aspect, an embodiment of the present disclosure provides a touch display apparatus, which includes any array substrate as described above.

In another aspect, an embodiment of the present disclosure provides a preparation method of an array substrate, which is used for preparing any array substrate as described above. The preparation method includes: forming a plurality of pixel units and a plurality of touch signal lines on a base substrate. At least one pixel unit includes a plurality of sub-pixels; two touch signal lines are arranged in the pixel unit, and the two touch signal lines are located on a side of a data line connected with one sub-pixel of the pixel unit.

In some exemplary embodiments, the forming the plurality of pixel units and the plurality of touch signal lines on the base substrate, includes: forming a first conductive layer on the base substrate, wherein the first conductive layer at least includes control electrodes of a plurality of switching elements and a plurality of gate lines; forming a semiconductor layer on a side of the first conductive layer away from the base substrate, wherein the semiconductor layer at least includes: active layers of a plurality of switching elements; forming a second conductive layer on a side of the semiconductor layer away from the base substrate, wherein the second conductive layer includes first and second electrodes of a plurality of switching elements, a plurality of data lines, and a plurality of touch signal lines; and forming sequentially a first transparent conductive layer and a second transparent conductive layer on a side of the second conductive layer away from the base substrate. The first transparent conductive layer includes a plurality of touch electrodes, and the second transparent conductive layer includes a plurality of pixel electrodes; or, the first transparent conductive layer includes a plurality of pixel electrodes, and the second transparent conductive layer includes a plurality of touch electrodes.

In some exemplary embodiments, the forming the plurality of pixel units and the plurality of touch signal lines on the base substrate, includes: forming a first conductive layer on the base substrate, wherein the first conductive layer at least includes control electrodes of a plurality of switching elements and a plurality of gate lines; forming a semiconductor layer on a side of the first conductive layer away from the base substrate, wherein the semiconductor layer at least includes: active layers of a plurality of switching elements; forming a first transparent conductive layer on a side of the semiconductor layer away from the base substrate, wherein the first transparent conductive layer at least includes a plurality of pixel electrodes; forming a second conductive layer on a side of the first transparent conductive layer away from the base substrate, wherein the second conductive layer includes first and second electrodes of a plurality of switching elements, a plurality of data lines, and a plurality of touch signal lines; forming a second transparent conductive layer on a side of the second conductive layer away from the base substrate, wherein the second transparent conductive layer at least includes a plurality of common electrodes.

Other aspects may be comprehended upon reading and understanding of the drawings and the detailed descriptions.

### BRIEF DESCRIPTION OF DRAWINGS

Accompanying drawings are used to provide a further understanding of technical solutions of the present disclosure and constitute a part of the specification to explain the technical solutions of the present disclosure together with embodiments of the present disclosure, and do not constitute any limitation on the technical solutions of the present disclosure. Shapes and sizes of one or more components in the accompanying drawings do not reflect real scales, and are only for a purpose of schematically illustrating contents of the present disclosure.

FIG. 1 is a schematic diagram of a touch structure of a touch display apparatus.

FIG. 2 is a schematic diagram of an arrangement of touch signal lines of an array substrate according to at least one embodiment of the present disclosure.

FIG. 3 is a schematic partial top view of an array substrate according to at least one embodiment of the present disclosure.

FIG. 4A is a schematic partial sectional view along a P-P direction in FIG. 3.

FIG. 4B is a schematic partial sectional view along a Q-Q direction in FIG. 3.

FIG. 5A is a schematic top view of an array substrate after the array substrate in FIG. 3 forms a first conductive layer.

FIG. 5B is a schematic top view of an array substrate after the array substrate in FIG. 3 forms a semiconductor layer.

FIG. 5C is a schematic top view of an array substrate after the array substrate in FIG. 3 forms a second conductive layer.

FIG. 5D is a schematic top view of an array substrate after the array substrate in FIG. 3 forms a second insulating layer.

FIG. 5E is a schematic top view of an array substrate after the array substrate in FIG. 3 forms a first transparent conductive layer.

FIG. 6 is another schematic partial top view of an array substrate according to at least one embodiment of the present disclosure.

FIG. 7 is a schematic partial sectional view along an R-R direction in FIG. 6.

FIG. 8 is another schematic partial top view of an array substrate according to at least one embodiment of the present disclosure.

FIG. 9A is a schematic partial sectional view along an A-A direction in FIG. 8.

FIG. 9B is a schematic partial sectional view along a B-B direction in FIG. 8.

FIG. 10A is a schematic top view of an array substrate after the array substrate in FIG. 8 forms a first conductive layer.

FIG. 10B is a schematic top view of an array substrate after the array substrate in FIG. 8 forms a semiconductor layer.

FIG. 10C is a schematic top view of an array substrate after the array substrate in FIG. 8 forms a first transparent conductive layer.

FIG. 10D is a schematic top view of an array substrate after the array substrate in FIG. 8 forms a second conductive layer.

### DETAILED DESCRIPTION

Hereinafter the embodiments of the present disclosure will be described in detail with reference to the accompanying drawings. The embodiments may be implemented in a plurality of different forms. Those of ordinary skills in the art will readily understand a fact that implementations and contents may be transformed into one or more of forms without departing from the spirit and scope of the present disclosure. Therefore, the present disclosure should not be construed as being limited only to what is described in the following embodiments. The embodiments and features in the embodiments in the present disclosure may be combined randomly if there is no conflict.

In the drawings, a size of one or more constituent elements, or a thickness or a region of a layer, is sometimes exaggerated for clarity. Therefore, an implementation of the present disclosure is not necessarily limited to the size, and shapes and sizes of a plurality of components in the drawings do not reflect real scales. In addition, the drawings schematically show ideal examples, and an implementation of the present disclosure is not limited to the shapes or values shown in the drawings.

The “first”, “second”, “third” and other ordinal numbers in the present disclosure are used to avoid confusion of constituent elements, not to provide any quantitative limitation. The “plurality of” in the present disclosure means two or more than two.

In the present disclosure, for the sake of convenience, wordings such as “central”, “upper”, “lower”, “front”, “rear”, “vertical”, “horizontal”, “top”, “bottom”, “inner”, “outer” and the others describing orientations or positional relations are used to depict positional relations of constituent elements with reference to the drawings, which are only for convenience of describing the specification and simplifying the description, rather than indicating or implying that the device or element referred to must have a specific orientation, or must be constructed and operated in a particular orientation, and therefore, those wordings cannot be construed as limitations on the present disclosure. The positional relations of the constituent elements may be appropriately changed according to a direction in which constituent elements are described. Therefore, the wordings are not limited in the specification, and may be replaced appropriately according to situations.

In the present disclosure, the terms “installed”, “connected”, and “coupled” shall be understood in their broadest sense unless otherwise explicitly specified and defined. For example, a connection may be a fixed connection, or a detachable connection, or an integrated connection; it may be a mechanical connection, or an electrical connection; it may be a direct connection, or an indirect connection through middleware, or an internal connection between two elements. Those of ordinary skill in the art may understand the meanings of the terms in the present disclosure according to specific situations.

In the present disclosure, a transistor refers to an element including at least three terminals, namely, a gate electrode, a drain electrode, and a source electrode. The transistor has a channel region between the drain electrode (a drain electrode terminal, a drain region or a drain) and the source electrode (a source electrode terminal, a source region or a source), and current may flow through the drain electrode, the channel region and the source electrode. In the present disclosure, the channel region refers to a region through which the current mainly flows.

In the present disclosure, to distinguish two electrodes of a transistor except a gate electrode, one of the electrodes is referred to as a first electrode and the other electrode is referred to as a second electrode. The first electrode may be a source electrode or a drain electrode, and the second electrode may be a drain electrode or a source electrode. In addition, the gate electrode of the transistor is referred to as a control electrode. Functions of the “source electrode” and the “drain electrode” are sometimes interchangeable in a case where transistors with opposite polarities are used or in a case where the current direction changes during circuit operation. Therefore, in the present disclosure, the “source electrode” and the “drain electrode” are interchangeable.

In the present disclosure, “an electrical connection” includes a case where constituent elements are connected via an element having an electrical function. The “element having a certain electrical action” is not particularly limited as long as it may transmit and receive electrical signals to/from connected constituent elements. Examples of the “element having an electrical function” not only include electrodes and wirings, but also include switching elements such as transistors, resistors, inductors, capacitors, and other elements with one or more functions, etc.

In the present disclosure, “parallel” refers to a state in which an angle formed by two straight lines is above −10 degrees and below 10 degrees, and thus may include a state in which the angle is above −5 degrees and below 5 degrees. In addition, “perpendicular” refers to a state in which an angle formed by two straight lines is above 80 degrees and below 100 degrees, and thus may include a state in which the angle is above 85 degrees and below 95 degrees.

In the present disclosure, “about” and “approximately” refer to situations where limits are not strictly defined and process and measurement errors are allowed.

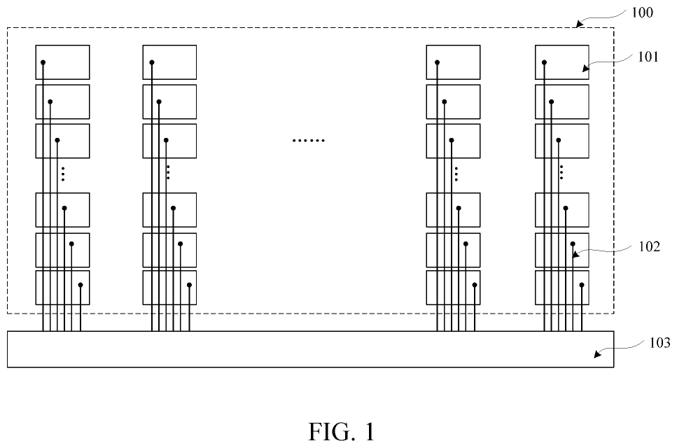

FIG. 1 is a schematic diagram of a touch structure of a touch display apparatus. The touch display apparatus shown in FIG. 1 may be an In cell touch display apparatus using a self-capacitance touch technology. As shown in FIG. 1, in the In cell touch display apparatus, a touch structure includes a plurality of touch sensing blocks (used as self-capacitance electrodes) 101 arranged in an array, and touch signal lines 102 electrically connected with the touch sensing blocks 101, respectively. Black dots in FIG. 1 indicate electrical connections. A touch circuit 103 is located on one side of a touch region 100 of the touch display apparatus. The touch signal lines 102 electrically connect the touch sensing blocks 101 to the touch circuit 103. When touching, a touch object (e.g., a person's finger) touches the touch display apparatus, and a capacitance of a touch sensing block 101 at a touch point will change. The touch circuit 103 determines a touch position by detecting self-capacitance change of the touch sensing block 101. In some examples, a size of a touch sensing block is in a millimeter level, for example, it may be about 5 mm*5 mm, while a size of a pixel unit in a display structure is in a micron level, so one touch sensing block may correspond to a plurality of pixel units in the display structure. In some embodiments, an arrangement of touch signal lines has an impact on a pixel aperture ratio, thus affecting the performance of the touch display apparatus.

At least one embodiment of the present disclosure provides an array substrate, which includes a base substrate, a plurality of pixel units and a plurality of touch signal lines that are arranged on the base substrate. At least one pixel unit includes a plurality of sub-pixels. Two touch signal lines are arranged in a pixel unit, and the two touch signal lines are located on one side of a data line connected with one sub-pixel of the pixel unit.

In this embodiment, by arranging two touch signal lines in the pixel unit, a situation where too many touch signal lines occupy a pixel aperture is avoided, thereby improving a transmittance and a display effect.

In some exemplary embodiments, the array substrate of this embodiment may adopt a self-capacitance touch technology. The array substrate includes a pixel electrode and a common electrode, and the common electrode is reused as a touch electrode. In a display stage, a common electrode signal is provided to a common electrode through a touch signal line to achieve a display function. In a touch stage, a touch signal detected by a common electrode is transmitted through a touch signal line to achieve a touch function. In some examples, a plurality of touch signal lines and a plurality of touch sensing blocks are connected in one-to-one correspondence, and each touch sensing block may include a plurality of common electrodes reused as touch electrodes, for example, the common electrodes of sub-pixels of tens multiplying by tens. A touch signal line connected with a touch sensing block may be connected to a driving integrated circuit integrating display and touch functions.

In some exemplary embodiments, a touch display apparatus including the array substrate of this embodiment may be a liquid crystal display apparatus. The touch display apparatus may include an array substrate of this embodiment, an opposite substrate, and a liquid crystal layer disposed between the array substrate and the opposite substrate. In some examples, a touch display apparatus may be an Advanced Super Dimension Switch (ADS) type display apparatus, or a High-Advanced Dimension Switch (HADS) type touch display apparatus with a high aperture ratio. A pixel electrode and a common electrode included in an array substrate are used for generating an electric field for controlling deflection of liquid crystal molecules in a liquid crystal layer. However, this embodiment is not limited to this.

In some exemplary embodiments, a pixel unit includes a first sub-pixel, a second sub-pixel, and a third sub-pixel arranged sequentially. Two touch signal lines arranged in a pixel unit may be located on one side of a data line connected with the first sub-pixel of the pixel unit. In some examples, a pixel unit may include three sub-pixels, such as a blue sub-pixel, a red sub-pixel, and a green sub-pixel, and the three sub-pixels are sequentially arranged in an order of the blue sub-pixel, the green sub-pixel, and a red sub-pixel. Two touch signal lines arranged in the pixel unit may be located on one side of a data line connected with the blue sub-pixel, or at one side of a data line connected with the red sub-pixel, or at one side of a data line connected with the green sub-pixel. However, this embodiment is not limited to this.

In some exemplary embodiments, a plurality of touch signal lines and a plurality of data lines are structures in a same layer. The plurality of touch signal lines extend along an extension direction of the data lines. In this exemplary embodiment, by arranging touch signal lines and second signal lines in the same layer, an arrangement of the touch signal lines can be facilitated.

In some exemplary embodiments, the array substrate may further include a first transparent conductive layer and a second transparent conductive layer. The second transparent conductive layer is located on a side of the first transparent conductive layer away from the base substrate. The first transparent conductive layer may include a plurality of common electrodes and the second transparent conductive layer may include a plurality of pixel electrodes. Or, the first transparent conductive layer may include a plurality of pixel electrodes, and the second transparent conductive layer may include a plurality of common electrodes. In this example, the common electrode is reused as the touch electrode, which is connected with the touch signal line. However, this embodiment is not limited to this.

In some exemplary embodiments, common electrodes of a plurality of sub-pixels of a pixel unit are of an integrated structure, and common electrodes of adjacent pixel units are connected through a first connection unit. In some examples, a second transparent conductive layer includes a plurality of common electrodes, and the first connection unit and the connected common electrode thereof may be of an integral structure. In this example, a plurality of mutually connected and spaced common electrodes are connected to form a touch sensing block and connected with a touch signal line. However, this embodiment is not limited to this.

In some exemplary embodiments, overlapping areas of pixel electrodes of a plurality of sub-pixels of a pixel unit and corresponding common electrodes are approximately the same. For example, an overlapping area of a pixel electrode of a first sub-pixel of a pixel unit and a corresponding common electrode is approximately equal to that of a pixel electrode of a second sub-pixel and a corresponding common electrode, and is approximately equal to that of a pixel electrode of a third sub-pixel and a corresponding common electrode. This exemplary embodiment may ensure that storage capacitances are approximately the same.

In some exemplary embodiments, an orthographic projection of a common electrode on a base substrate covers an orthographic projection of a data line on the base substrate.

In some exemplary embodiments, an orthographic projection of a common electrode on a base substrate is not overlapped with an orthographic projection of a touch signal line on the base substrate. This exemplary embodiment may reduce a load of the touch signal line.

In some exemplary embodiments, both the first transparent conductive layer and the second transparent conductive layer are located on one side of the plurality of touch signal lines away from the base substrate. For example, the first transparent conductive layer includes a plurality of pixel electrodes, and the second transparent conductive layer includes a plurality of common electrodes; or, the first transparent conductive layer includes a plurality of common electrodes, and the second transparent conductive layer includes a plurality of pixel electrodes.

In some exemplary embodiments, in a plane perpendicular to an array substrate, the array substrate at least includes a base substrate, and a first conductive layer, a semiconductor layer, a second conductive layer, a first transparent conductive layer, and a second transparent conductive layer that are disposed on the base substrate. The first conductive layer at least includes control electrodes of a plurality of switching elements and a plurality of gate lines. The semiconductor layer at least includes active layers of a plurality of switching elements. The second conductive layer at least includes first and second electrodes of a plurality of switching elements, a plurality of data lines, and a plurality of touch signal lines. An organic insulating layer is arranged between the second conductive layer and the first transparent conductive layer. In this exemplary embodiment, by arranging the organic insulating layer between the second conductive layer where the touch signal lines are located and the first transparent conductive layer, a capacitance between the touch signal lines and the first transparent conductive layer may be reduced.

In some exemplary embodiments, at least one switching element is located at an intersection position of a data line and a gate line.

In some exemplary embodiments, the first transparent conductive layer is located on one side of a plurality of touch signal lines close to the base substrate, and the second transparent conductive layer is located on one side of the plurality of touch signal lines away from the base substrate. The first transparent conductive layer includes a plurality of pixel electrodes, and the second transparent conductive layer includes a plurality of common electrodes.

A solution of this embodiment will be illustrated below through a plurality of examples. An array substrate according to this exemplary embodiment being included in an ADS type touch display apparatus using a self-capacitance touch technology is taken as an example for description. For example, a touch display apparatus may include the array substrate according to this embodiment, an opposite substrate, and a liquid crystal layer disposed between the array substrate and the opposite substrate. A pixel electrode and a common electrode included in the array substrate may generate an electric field for controlling deflection of liquid crystal molecules in the liquid crystal layer. The opposite substrate may include a base substrate, a color film layer, and a black matrix.

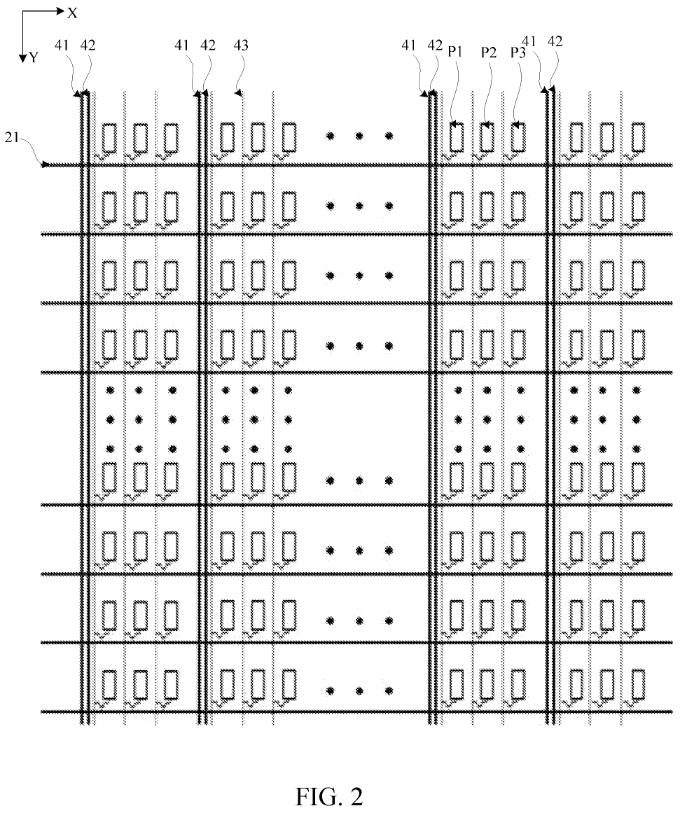

FIG. 2 is a schematic diagram of an arrangement of touch signal lines of an array substrate according to at least one embodiment of the present disclosure. As shown in FIG. 2, the array substrate of this embodiment includes a base substrate, and a plurality of pixel units, a plurality of touch signal lines (for example, including a plurality of first touch signal lines 41 and a plurality of second touch signal lines 42), a plurality of data lines 43, and a plurality of gate lines 21 that are disposed on the base substrate. At least one pixel unit includes a first sub-pixel P1, a second sub-pixel P2, and a third sub-pixel P3. The first sub-pixel P1, the second sub-pixel P2, and the third sub-pixel P3 may be sequentially arranged along a first direction X. For example, the first sub-pixel P1 is a blue sub-pixel, the second sub-pixel P2 is a green sub-pixel, and the third sub-pixel P3 is a red sub-pixel. However, this embodiment is not limited to this.

In some exemplary embodiments, a plurality of data lines 43 extend along a second direction Y, and a plurality of gate lines 21 extend along a first direction X. The plurality of data lines 43 and the plurality of gate lines 21 intersect to form a plurality of sub-pixel regions, and each sub-pixel region is provided with a sub-pixel. A plurality of touch signal lines extend along the second direction Y. The second direction Y intersects with the first direction X, for example, the second direction Y and the first direction X are perpendicular to each other. Two touch signal lines (for example, a first touch signal line 41 and a second touch signal line 42) are arranged in one pixel unit. In some examples, the first touch signal line 41 and the second touch signal line 42 may be located on one side of a data line 43 connected to a first sub-pixel P1 away from the first sub-pixel P1. However, this embodiment is not limited to this. For example, the first touch signal line 41 and the second touch signal line 42 may be located between a first sub-pixel P1 and a second sub-pixel P2, and on one side of a data line 43 connected to the second sub-pixel P2 away from a second sub-pixel P2. Or, a first touch signal line 41 and a second touch signal line 42 may be located between a second sub-pixel P2 and a third sub-pixel P3, and on one side of a data line 43 connected to the third sub-pixel P3 away from the third sub-pixel P3.

In some exemplary embodiments, two touch signal lines are provided in each pixel unit, and positions of the two touch signal lines in a corresponding pixel unit may be the same. For example, in each pixel unit, two touch signal lines are located on one side of a data line connected to a first sub-pixel. However, this embodiment is not limited to this. In some examples, positions of two touch signal lines correspondingly provided in different pixel units may be different. For example, two touch signal lines provided in some pixel units may be located on one side of a data line connected to a first sub-pixel, while two touch signal lines provided in some pixel units may be located between the first sub-pixel and the second sub-pixel and on one side of a data line connected to the second sub-pixel.

In the above embodiments, the first sub-pixel P1, the second sub-pixel P2, and the third sub-pixel P3 included in at least one pixel unit are sequentially arranged along the first direction X, that is, in a form of rows. In an exemplary embodiment, the first sub-pixel P1, the second sub-pixel P2, and the third sub-pixel P3 included in at least one pixel unit may be sequentially arranged along a second direction Y, that is, in a form of columns. In this exemplary embodiment, a first touch signal line 41 and a second touch signal line 42 are located on one side of a same column of sub-pixels, either on a left side or on a right side of the column of sub-pixels, which is not limited here.

In this exemplary embodiment, both a data line 43 and a gate line 21 are connected to sub-pixels of a corresponding column through switching elements, such as thin film transistors.

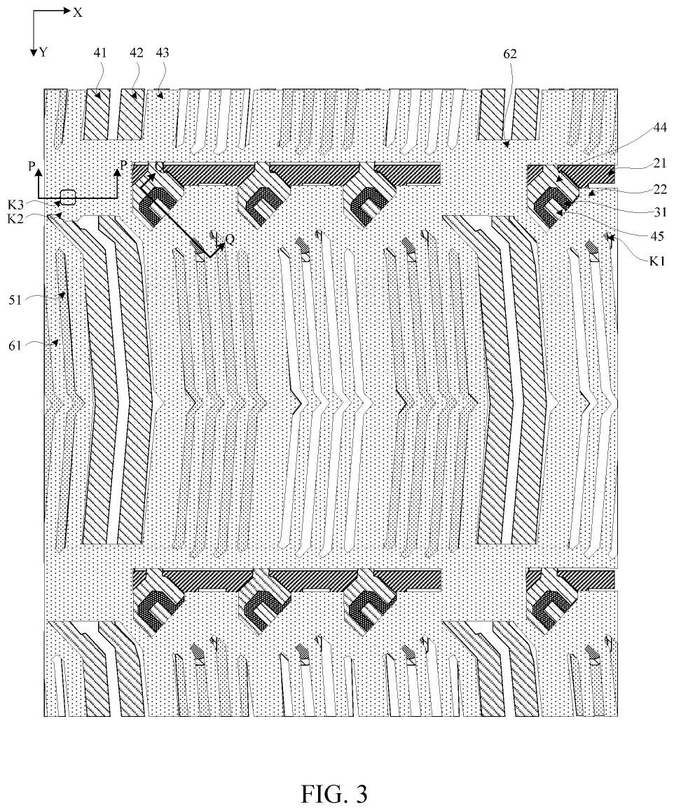

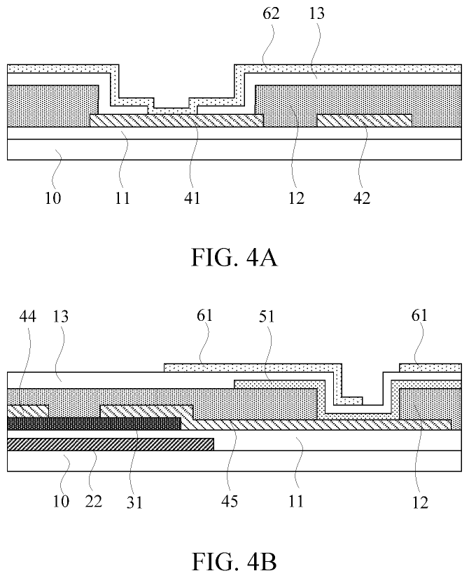

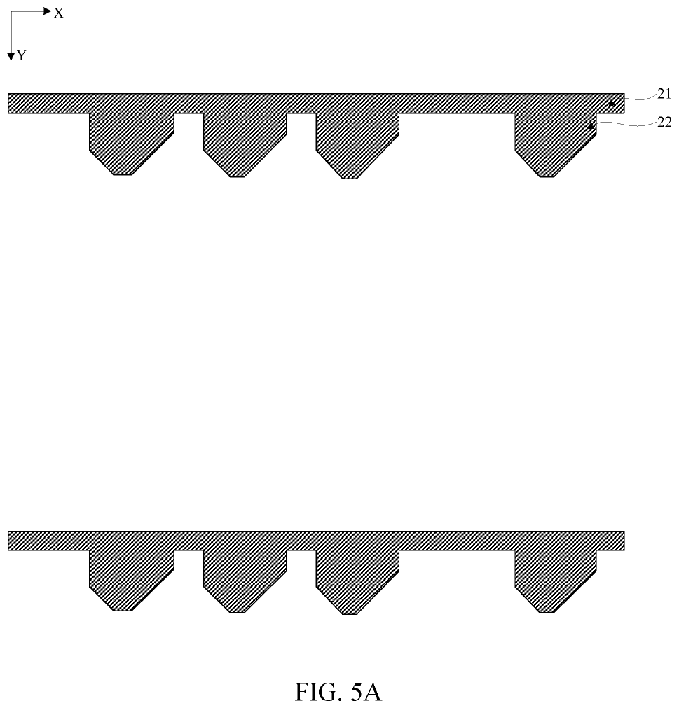

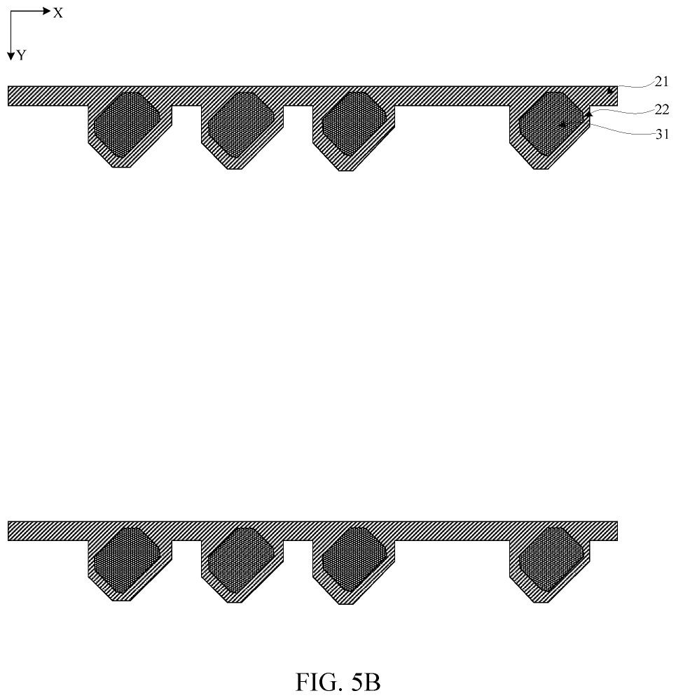

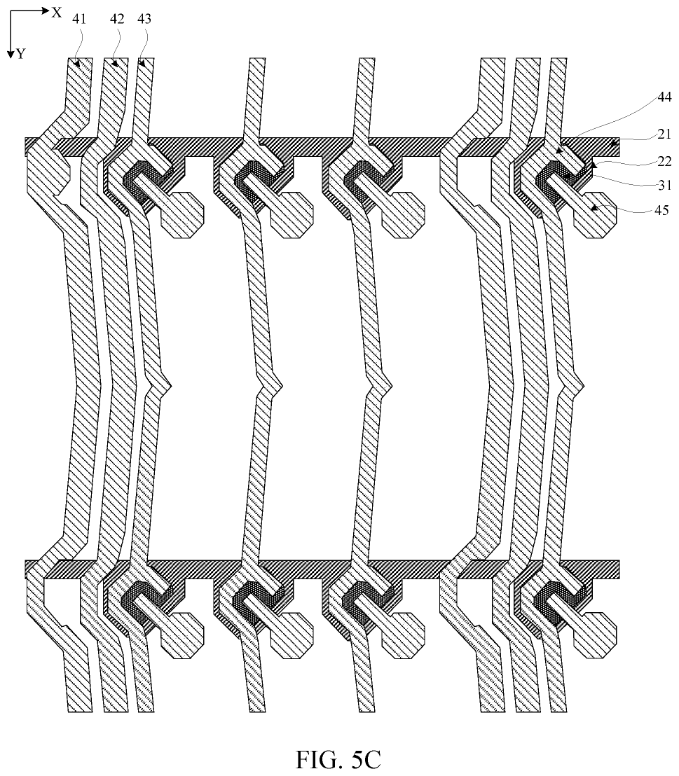

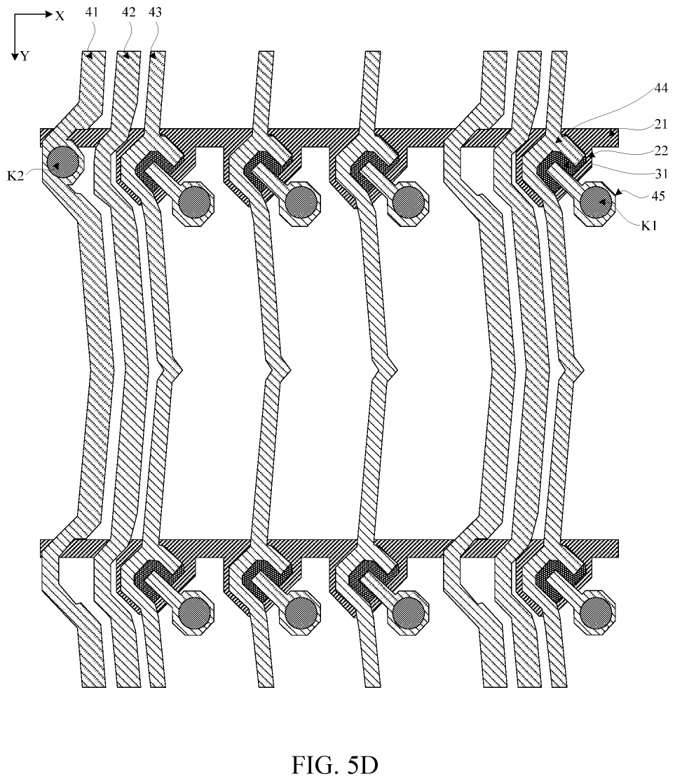

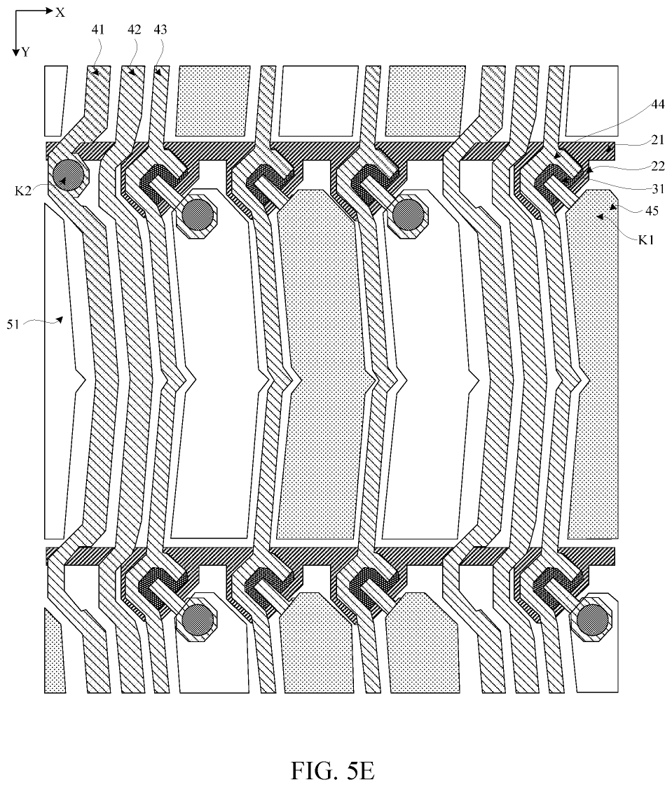

In this exemplary embodiment, the two touch signal lines, i.e., the first touch signal line 41 and the second touch signal line 42, are located on one side of a corresponding data line away from a switching element connected to the data line. FIG. 3 is a schematic partial top view of an array substrate according to at least one embodiment of the present disclosure. FIG. 4A is a schematic partial sectional view along a P-P direction in FIG. 3. FIG. 4B is a schematic partial sectional view along a Q-Q direction in FIG. 3. FIG. 5A is a schematic top view of an array substrate after the array substrate in FIG. 3 forms a first conductive layer. FIG. 5B is a schematic top view of an array substrate after the array substrate in FIG. 3 forms a semiconductor layer. FIG. 5C is a schematic top view of an array substrate after the array substrate in FIG. 3 forms a second conductive layer. FIG. 5D is a schematic top view of an array substrate after the array substrate in FIG. 3 forms a second insulating layer. FIG. 5E is a schematic top view of an array substrate after the array substrate in FIG. 3 forms a first transparent conductive layer. In illustration of this example, partial structures of three sub-pixels and other sub-pixels are mainly illustrated.

In some exemplary embodiments, as shown in FIGS. 3 to 5E, an array substrate includes a base substrate 10, and a plurality of data lines 43 and a plurality of gate lines 21 disposed on the base substrate 10. The plurality of gate lines 21 are located on a first conductive layer, extend along a first direction X, and are sequentially arranged along a second direction Y which is different from the first direction X. The plurality of data lines 43 are located on a second conductive layer, extend along the second direction Y, and are sequentially arranged along the first direction X. The first direction X and the second direction Y intersect. The first direction X is perpendicular to the second direction Y, for example. The second conductive layer is located on a side of the first conductive layer away from the base substrate 10. The plurality of data lines 43 and the plurality of gate lines 21 intersect to form a plurality of sub-pixel regions. A region defined by intersection of adjacent data lines 43 and adjacent gate lines 21 is a sub-pixel region. A sub-pixel region includes an aperture region and a non-aperture region surrounding the aperture region. In some examples, the non-aperture region is a region that is blocked by a black matrix of an opposite substrate of the array substrate, and the aperture region is a region that is not blocked by the black matrix. Adjacent gate lines 21 and data lines 41 are located in non-aperture regions. In some examples, the array substrate of this embodiment is used for achieving a display function, an aperture region of each sub-pixel region is configured to perform display, and a non-aperture region surrounds the aperture region and does not perform display. However, this embodiment is not limited to this. In some examples, the array substrate may be used for implementing other functions.

In some exemplary embodiments, as shown in FIGS. 3 to 5E, the array substrate further includes a plurality of first touch signal lines 41 and a plurality of second touch signal lines 42. The first touch signal line 41 is adjacent to the second touch signal line 42. The second touch signal line 42 is adjacent to a data line 43 connected to a sub-pixel in a corresponding pixel unit. The plurality of first touch signal lines 41 and the plurality of touch signal lines 42 extend along an extension direction of data lines 43 (i.e., a second direction Y) and are sequentially arranged along an extension direction of gate lines 21 (i.e., a first direction X). The plurality of first touch signal lines 41 and the plurality of second touch signal lines 42 may be located in a second conductive layer and in a same layer as a plurality of data lines 43.

In some exemplary embodiments, as shown in FIG. 3, orthographic projections of a first touch signal line 41 and a second touch signal line 42 on the base substrate 10 intersect with an orthographic projection of a gate line 21 on the base substrate 10. For example, an orthographic projection of a first touch signal line 41 has a first width at a position overlapping with the orthographic projection of a gate line 21 and a second width at a position not overlapping with the orthographic projection of a gate line 21, and the first width is smaller than the second width. An orthographic projection of a second touch signal line 42 has a third width at a position overlapping with the orthographic projection of a gate line 21 and a fourth width at a position not overlapping with the orthographic projection of a gate line 21, and the third width is smaller than the fourth width. In some examples, the second width and the fourth width may be substantially the same. In this example, by reducing an overlapping area between a touch signal line and a gate line, a load of an array substrate may be reduced. In the present disclosure, a width represents a characteristic dimension in a vertical direction of an extension direction of a wiring.

In some exemplary embodiments, as shown in FIG. 3, orthographic projections of a first touch signal line 41 and a second touch signal line 42 on the base substrate 10 are not overlapped with an orthographic of an aperture region of a sub-pixel region on the base substrate 10. In other words, a first touch signal line 41 and a second touch signal line 42 are located in a non-aperture region. A pixel electrode 51 and a common electrode 61 are provided in an aperture region of a sub-pixel region. The common electrode 61 is reused as a touch electrode. In a display stage, a common electrode signal is provided to the common electrode 61 through a touch signal line to achieve a display function. In a touch stage, a touch signal detected by the common electrode 61 is transmitted through a touch signal line to achieve a touch function. A plurality of common electrodes 61 are connected to each other to form a touch sensing block. For example, common electrodes 61 spaced apart from each other in a plurality of pixel units may be connected to each other to form a touch sensing block.

In some exemplary embodiments, as shown in FIG. 3, the array substrate further includes a plurality of switching elements. A switching element is located at an intersection position of a data line 43 and a gate line 21. A switching element may be a Thin Film Transistor (TFT). A switching element may include a control electrode 22, an active layer 31, a first electrode 44, and a second electrode 45. A gate electrode 22 of a switching element and a gate line 21 may be of an integral structure. A first electrode 44 of a switching element may be connected to a data line 43, for example, a first electrode 44 of a switching element and a data line 43 may be of an integral structure. A second electrode 45 of a switching element may be electrically connected to a pixel electrode 51 through a first via K1. An active layer 31 may include a channel region, a first doped region, and a second doped region. The channel region may not be doped with impurities and has semiconductor characteristics. The first doped region and the second doped region may be on two sides of the channel region and doped with impurities, and thus have conductivity. Impurities may vary depending on a type of a transistor.

In some exemplary embodiments, as shown in FIG. 3, the array substrate further includes a first transparent conductive layer and a second transparent conductive layer. The first transparent conductive layer and the second transparent conductive layer are located on a side of a second conductive layer away from the base substrate 10. The first transparent conductive layer includes a plurality of pixel electrodes 51, and the second transparent conductive layer includes a plurality of common electrodes 61 and a first connection unit 62. A pixel electrode 51 is disposed in a sub-pixel region. Common electrodes 61 of a plurality of sub-pixels of a pixel unit may be of an integral structure. Common electrodes 61 of adjacent pixel units may be connected through a first connection unit 62. Common electrodes 61 and a first connection unit 62 may be of an integral structure. In this example, a first connection unit 62 is used for electrically connecting a plurality of common electrodes 61 spaced apart from each other to form a touch sensing block, so that the touch sensing block has a mesh structure, thus the touch sensing block has a smaller resistance. In this embodiment, a quantity of common electrodes included in one touch sensing block is not limited.

In some exemplary embodiments, as shown in FIG. 3, a first connection unit 62 of a second transparent conductive layer is connected with a first touch signal line 41 through a second via K2 formed in a second insulating layer and a third via K3 formed in a third insulating layer, thereby achieving electrical connection between a common electrode 61 and the first touch signal line 41. However, this embodiment is not limited to this.

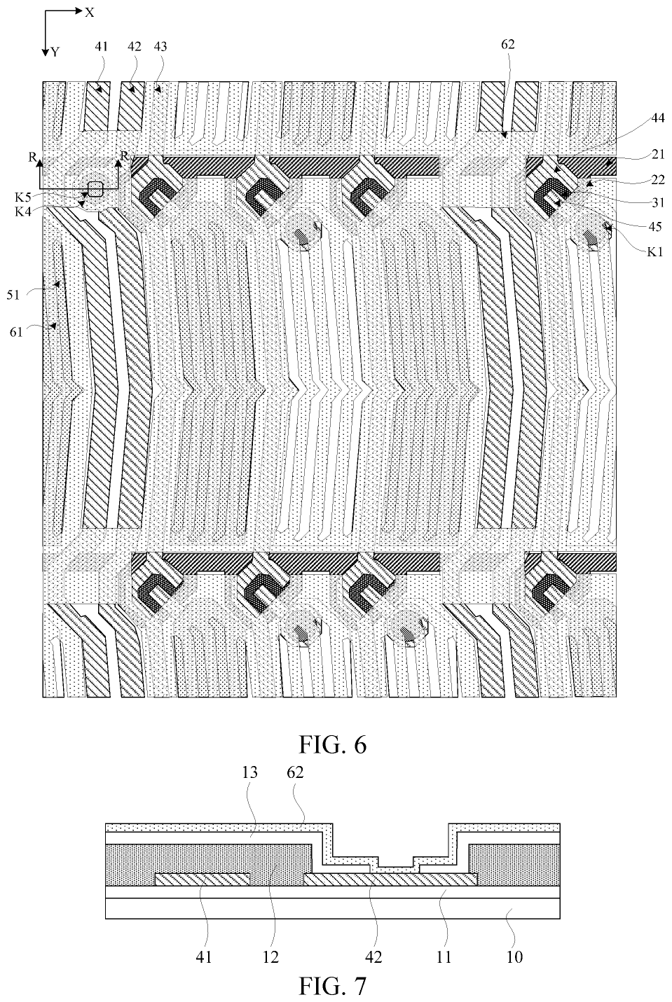

FIG. 6 is another schematic partial top view of an array substrate according to at least one embodiment of the present disclosure. FIG. 7 is a schematic partial sectional view along an R-R direction in FIG. 6. FIG. 3 is a schematic diagram showing a connection position of a first touch signal line 41 and a second transparent conductive layer, and FIG. 6 is a schematic diagram showing a connection position of a second touch signal line 42 and a second transparent conductive layer. In some exemplary embodiments, as shown in FIGS. 6 and 7, a second touch signal line 42 is connected with a first connection unit 62 through a fourth via K4 provided on a second insulating layer and a fifth via K5 provided on a third insulating layer, thereby achieving electrical connection between the second touch signal line 42 and a common electrode 61.

Hereinafter, technical solutions of the embodiments will be further described through a preparation process of an array substrate of an exemplary embodiment with reference to FIGS. 3 to 7. The “patterning process” mentioned in the present embodiment includes processings, such as thin film layer deposition, photoresist coating, mask exposure, development, etching, and photoresist stripping. The deposition may adopt any one or more of sputtering, evaporation and chemical vapor deposition, the coating may be selected from any one or more of spraying and spin coating, and etching may adopt any one or more of dry etching and wet etching. A “thin film” refers to a layer of thin film manufactured by deposition or coating of a certain material on a substrate. If a patterning process or a photolithography process is not needed for the “thin film” during a whole manufacturing process, the “thin film” may be referred to as a “layer”. If a patterning process or a photolithography process is needed for the “thin film” during the whole manufacturing process, it is referred to as a “thin film” before the patterning process and referred to as a “layer” after the patterning process. The “layer” after the patterning process or photolithography process includes at least one “pattern”.

In the present disclosure, “A and B are provided on the same layer” means that A and B are formed at the same time by the same patterning process. The “same layer” does not always mean that a thickness or a height of the layer are the same in a sectional view. “An orthographic projection of A contains an orthographic projection of B” means that the orthographic projection of B falls within the scope of the orthographic projection of A, or the orthographic projection of A covers the orthographic projection of B.

The preparation process of the array substrate according to this embodiment may include following acts (1) to (6).

(1) A base substrate is provided.

In some exemplary embodiments, a base substrate 10 may be a transparent substrate, such as a quartz substrate, a glass substrate, or an organic resin substrate. However, this embodiment is not limited to this.

(2) A first conducting layer is formed.

In some exemplary embodiments, a conductive thin film is deposited on the base substrate 10, and the conductive thin film is patterned through a patterning process to form a first conducting layer, as shown in FIG. 5A. The first conductive layer at least includes a plurality of gate lines 21 and control electrodes 22 of a plurality of switching elements. The gate electrodes 22 of the plurality of switching elements and the gate lines 21 may be of an integral structure. The plurality of gate lines 21 extend along a first direction X and are sequentially arranged along a second direction Y.

(3) A semiconductor layer is formed.

In some exemplary embodiments, a first insulating thin film and a semiconductor thin film are sequentially deposited on the base substrate 10 formed with the aforementioned structure, and the semiconductor thin film is patterned through a patterning process to form a first insulating layer 11 and a pattern of a semiconductor layer disposed on the first insulating layer 11, as shown in FIG. 5B. In some examples, a semiconductor layer includes active layers 31 of a plurality of switching elements. The active layer 31 may include a channel region, a first doped region, and a second doped region. The channel region may not be doped with impurities and has semiconductor characteristics. The first doped region and the second doped region may be on two sides of the channel region and doped with impurities, and thus have conductivity. Impurities may vary depending on a type of a transistor (e.g., N-type or P-type). In some examples, a semiconductor thin film may be made of one or more materials such as amorphous indium gallium zinc oxide material (a-IGZO), zinc oxynitride (ZnON), indium zinc tin oxide (IZTO), amorphous silicon (a-Si), polysilicon (p-Si), hexathiophene, and polythiophene. That is, the present disclosure is applicable to transistors that are manufactured based on an Oxid technology, a silicon technology, and an organic technology. However, this embodiment is not limited to this.

(4) A second conductive layer is formed.

In some exemplary embodiments, a second conductive thin film is deposited on the base substrate 10 formed with the aforementioned structure, and the second conductive thin film is patterned through a patterning process to form a second conductive layer, as shown in FIG. 5C. A second conductive layer at least includes a plurality of data lines 43, a plurality of first touch signal lines 41, a plurality of second touch signal lines 42, and first electrodes 44 and second electrodes 45 of a plurality of switching elements. A plurality of data lines 43, a plurality of first touch signal lines 41, and a plurality of second touch signal lines 42 all extend along a second direction Y and are arranged at intervals along a first direction X. A first touch signal line 41 is adjacent to a second touch signal line 42, and the second touch signal line 42 is adjacent to a data line 43 connected to one sub-pixel of a pixel unit. For example, the first touch signal line 41 and the second touch signal line 42 are located on one side of a data line 43 connected to a first sub-pixel of a pixel unit.

In some examples, a switching element is located at an intersection position of a gate line 21 and a data line 43. A first electrode 44 of a switching element is overlapped with and is directly connected with a first doped region of an active layer 31, and a second electrode 45 is overlapped with and is directly connected with a second doped region of the active layer 31. A first electrode 44 of a switching element and an adjacent data line 43 may be of an integral structure. However, this embodiment is not limited to this.

(5) A second insulating layer and a first transparent conductive layer are formed.

In some exemplary embodiments, a second insulating thin film is coated on the base substrate 10 formed with the aforementioned structure, and a second insulating layer 12 is formed by masking, exposing, and developing the second insulating thin film, as shown in FIG. 5D. A plurality of first vias K1 and a plurality of second vias K2 are provided on the second insulating layer 12, and the second insulating layer 12 in the first vias K1 is removed to expose surfaces of second electrodes 45 of switching elements. The second insulating layer 12 in the plurality of second vias K2 is removed to expose surfaces of first touch signal lines 41.

Then, a first transparent conductive thin film is deposited on the base substrate 10 formed with the aforementioned structure, and a first transparent conductive thin film is patterned through a patterning process to form a first transparent conductive layer, as shown in FIG. 5E. The first transparent conductive layer includes a plurality of pixel electrodes 51. A pixel electrode 51 is located in a sub-pixel region formed by intersection of a data line 43 and a gate line 21. The pixel electrode 51 is connected to the second electrode 45 of the switching element through the first via K1. The pixel electrode 51 may be a sheet electrode.

In some exemplary embodiments, the second insulating layer 12 may be made of an organic material such as polyimide, acrylic, or polyethylene terephthalate. However, this embodiment is not limited to this.

(6) A second transparent conductive layer is formed.

In some exemplary embodiments, a third insulating thin film is deposited on the base substrate 10 formed with the aforementioned structure, and the third insulating thin film is patterned through a patterning process to form a pattern of a third insulating layer 13. A plurality of third vias K3 are formed on the third insulating layer 13. The third insulating layer 13 in the plurality of third vias K3 is etched off to expose surfaces of first touch signal line s41. An orthographic projection of a second via K2 on the base substrate 10 covers an orthographic projection of a third via K3 on the base substrate 10.

Then, a second transparent conductive thin film is deposited on the base substrate 10 formed with the aforementioned structure, and the second transparent conductive thin film is patterned to form a second transparent conductive layer, as shown in FIG. 3. The second transparent conductive layer at least includes a plurality of common electrodes 61 and a first connection unit 62. Common electrodes 61 of a plurality of sub-pixels of a pixel unit may be of an integral structure. An orthographic projection of a common electrode 61 on the base substrate 10 covers a data line connected to a sub-pixel of a pixel unit. An orthographic projection of a common electrode 61 on the base substrate 10 is not overlapped with orthographic projections of a first touch signal line 41 and a second touch signal line 42 on the base substrate 10. Common electrodes 61 of different pixel units may be connected through the first connection unit 62. The first connection unit 62 may be located at an intersection position of a touch signal line and a gate line 21. An orthographic projection of the first connection unit 62 on the base substrate 10 is overlapped with each of orthographic projections of a gate line 21, a first touch signal line 41, and a second touch signal line 42 on the base substrate 10.

In this exemplary embodiment, a common electrode is reused as a touch electrode, and a common electrode signal is applied to a common electrode in a display stage to achieve a display function, and a touch signal is applied to a common electrode in a touch stage to achieve a touch function. Therefore, a film layer on which a touch electrode is located does not need to be additionally manufactured, so that a manufacturing process is not performed and a thickness of an array substrate may be reduced.

In some exemplary embodiments, a common electrode 61 has a plurality of slits. The plurality of slits penetrate through the common electrode 61. Extension directions of the plurality of slits intersect with a second direction Y. The common electrode 61 may have slits in two different directions, thereby forming a dual domain structure. However, this embodiment is not limited to this. For example, a common electrode may form a single domain or multi-domain structure.

In some exemplary embodiments, the first insulating layer 11 and the third insulating layer 13 may be made of any one or more of silicon oxide (SiOx), silicon nitride (SiNx), and silicon oxynitride (SiON), and may be a single layer, a multi-layer, or a composite layer. The first conductive thin film and the second conductive thin film may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti. The first transparent conductive thin film and the second transparent conductive thin film may be made of a transparent conductive material, such as indium tin oxide (ITO) or indium zinc oxide (IZO). However, this embodiment is not limited to this.

Descriptions of a structure and a preparation process of a display substrate according to the embodiments of the present disclosure are merely illustrative. In some exemplary embodiments, according to actual needs, corresponding structures may be changed and patterning processes may be added or reduced. For example, a common electrode may be located between a base substrate and a pixel electrode, the pixel electrode has a slit, and the common electrode may be a sheet electrode structure without a slit, as a result, a touch electrode has a larger area, which is beneficial to enhancing touch performance. As the touch electrode is closer to the base substrate and has a larger area, a double-side touch mode may be achieved. In other words, in a front touch mode, a touch object (e.g., a user's finger) may touch on a side of a base substrate where a touch electrode is provided; and in a back touch mode, a touch object may touch on a side of a base substrate where a touch electrode is not provided. However, this embodiment is not limited to this.

According to a display substrate provided by this exemplary embodiment, two touch signal lines are arranged in each pixel unit, and the two touch signal lines are located on one side of a data line connected with one sub-pixel of a pixel unit, so that a situation where too many touch signal lines occupy a pixel aperture is avoided, thereby improving a transmittance and a display effect.

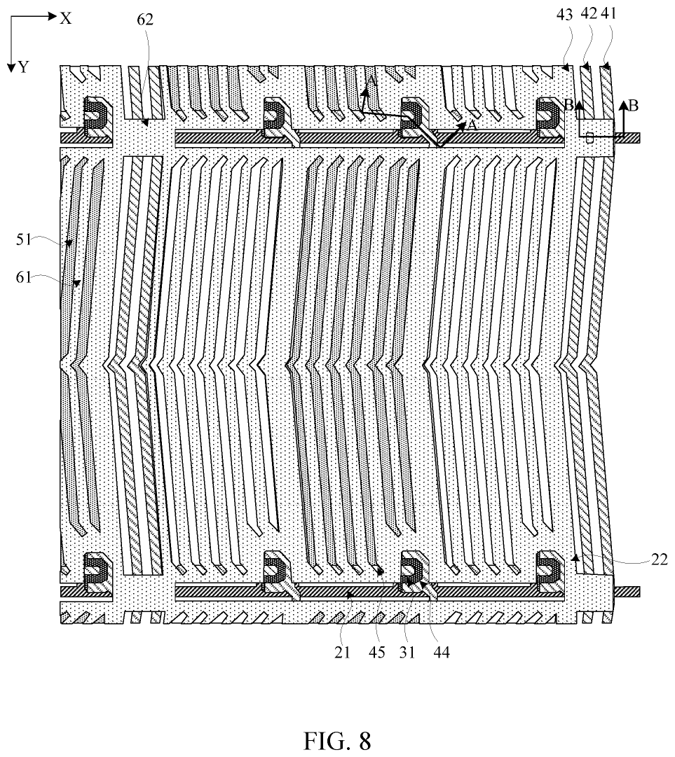

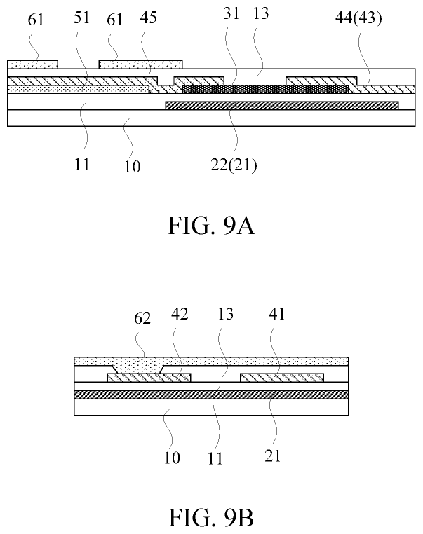

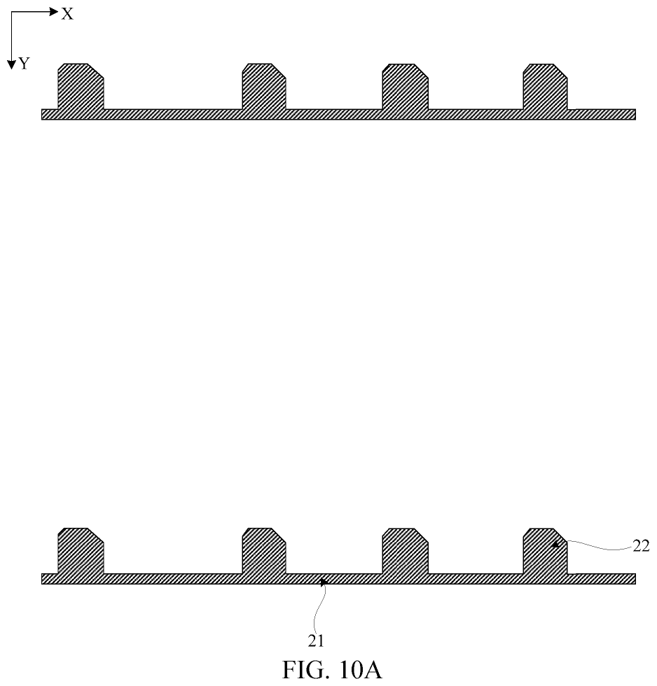

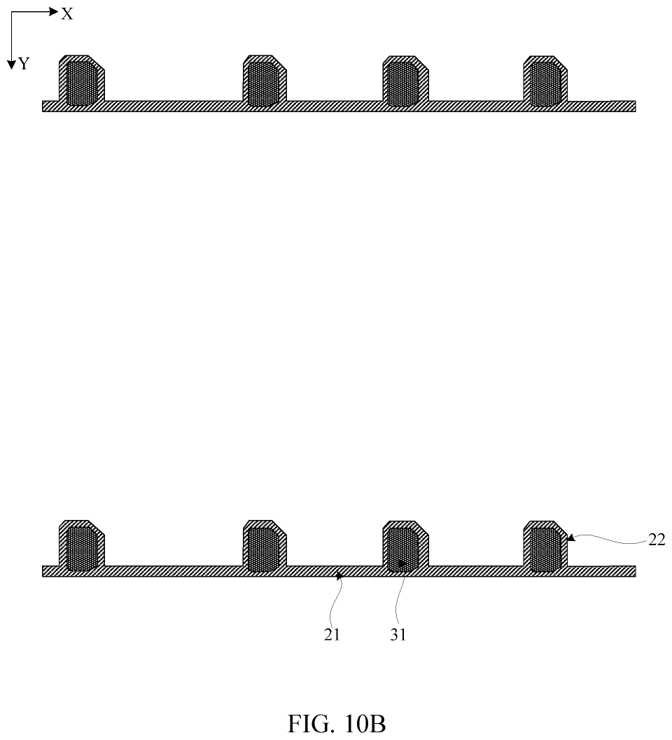

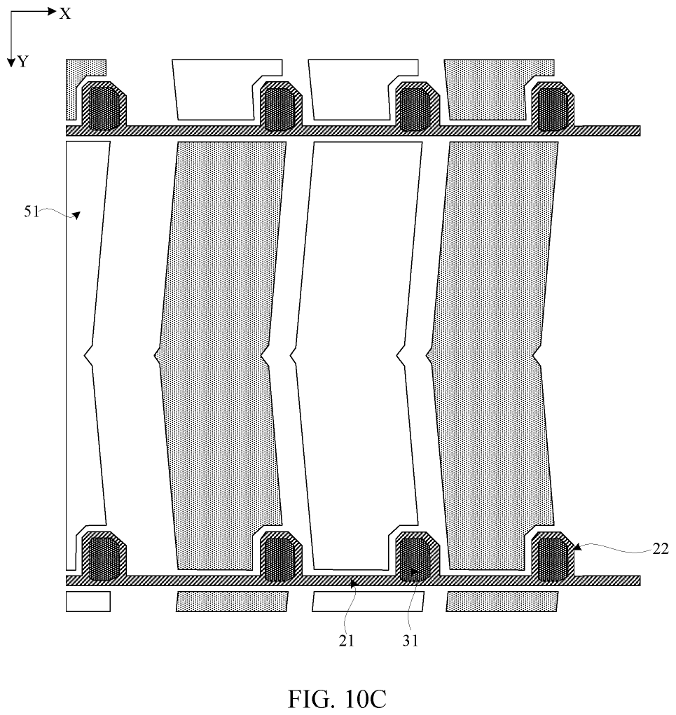

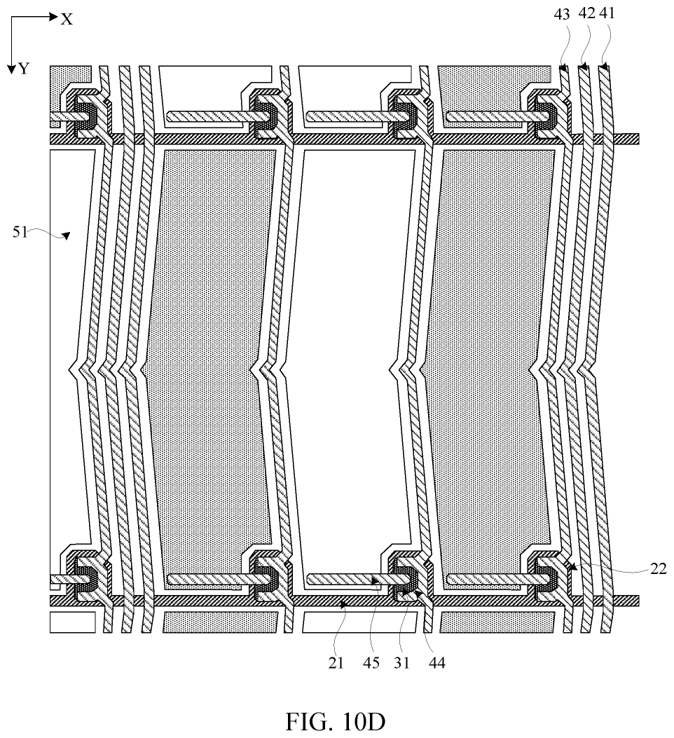

FIG. 8 is a schematic partial top view of an array substrate according to at least one embodiment of the present disclosure. FIG. 9A is a schematic partial sectional view along an A-A direction in FIG. 8. FIG. 9B is a schematic partial sectional view along a B-B direction in FIG. 8. FIG. 10A is a schematic top view of an array substrate after the array substrate in FIG. 8 forms a first conductive layer. FIG. 10B is a schematic top view of an array substrate after the array substrate in FIG. 8 forms a semiconductor layer. FIG. 10C is a schematic top view of an array substrate after the array substrate in FIG. 8 forms a first transparent conductive layer. FIG. 10D is a schematic top view of an array substrate after the array substrate in FIG. 8 forms a second conductive layer. In illustration of this example, partial structures of three sub-pixels and other sub-pixels are mainly illustrated.

In some exemplary embodiments, as shown in FIGS. 8 to 10D, in a plane perpendicular to an array substrate, the array substrate includes a base substrate, and a first conductive layer, a semiconductor layer, a first transparent conductive layer, a second conductive layer, and a second transparent conductive layer that are disposed on the base substrate. A first insulating layer 11 is disposed between the first conductive layer and the semiconductor layer, and a third insulating layer 13 is disposed between the second conductive layer and the second transparent conductive layer. The first insulating layer 11 and the third insulating layer 13 are inorganic insulating layers.

In some exemplary embodiments, the first conductive layer at least includes control electrodes 22 of a plurality of switching elements and a plurality of gate lines 21. The control electrodes 22 of the plurality of switching elements and one gate line 21 may be of an integral structure. The plurality of gate lines 21 extend along a first direction X and are sequentially arranged along a second direction Y. The semiconductor layer includes at least active layers 31 of a plurality of switching elements. The active layer 31 may include a channel region, a first doped region, and a second doped region. The channel region may not be doped with impurities and has semiconductor characteristics. The first doped region and the second doped region may be on two sides of the channel region and doped with impurities, and thus have conductivity. Impurities may vary depending on a type of a transistor (e.g., N-type or P-type). The first transparent conductive layer at least includes a plurality of pixel electrodes 51. The second conductive layer at least includes a plurality of data lines 43, a plurality of first touch signal lines 41, a plurality of second touch signal lines 42, and first electrodes 44 and second electrodes 45 of a plurality of switching elements. The plurality of data lines 43, the plurality of first touch signal lines 41, and the plurality of second touch signal lines 42 all extend along the second direction Y and are arranged at intervals along the first direction X. The first touch signal line 41 is adjacent to the second touch signal line 42, and the second touch signal line 42 is adjacent to a data line 43 connected to one sub-pixel of a pixel unit. For example, the first touch signal line 41 and the second touch signal line 42 are located on one side of a data line 43 connected to a first sub-pixel of a pixel unit. A switching element is located at an intersection position of a gate line 21 and a data line 43. A first electrode 44 of a switching element is overlapped with and is directly connected with a first doped region of an active layer 31, and a second electrode 45 is overlapped with and is directly connected with a second doped region of the active layer 31. A first electrode 44 of a switching element and an adjacent data line 43 may be of an integral structure. An orthographic projection of a second electrode 45 of a switching element on a base substrate 10 is overlapped with that of a pixel electrode 51 on the base substrate 10, and the second electrode 45 of the switching element is directly connected with the pixel electrode 51. For example, a pixel electrode 51 may be a sheet electrode, which is located in a sub-pixel region defined by intersection of a data line 43 and a gate line 21. The second transparent conductive layer at least includes a plurality of common electrodes 61 and a first connection unit 62. Common electrodes 61 of a plurality of sub-pixels of a pixel unit may be of an integral structure. Common electrodes 61 of different pixel units may be connected through the first connection unit 62. A common electrode 61 is reused as a touch electrode, and a plurality of common electrodes 61 are connected through the first connection unit 62 to form a touch sensing block, which is connected with a first touch signal line 41 or a second touch signal line 42.

In some exemplary embodiments, as shown in FIGS. 8 and 9B, a second touch signal line 42 may be connected with the first connection unit 62 through a via provided in the third insulating layer 13. The first connection unit 62 and an adjacent common electrode 61 are of an integral structure. In this way, electrical connection between a second touch signal line 42 and a plurality of common electrodes 61 can be achieved. A connection mode of a first touch signal line 41 and a common electrode is similar, and will not be repeated here.

In some exemplary embodiments, a common electrode 61 has a plurality of slits. The plurality of slits penetrate through the common electrode 61. Extension directions of the plurality of slits intersect with a second direction Y. A common electrode 61 may have slits in two different directions, thereby forming a dual domain structure. However, this embodiment is not limited to this. For example, a common electrode may form a single domain or multi-domain structure.

In some exemplary embodiments, a preparation process of an array substrate of this embodiment may include: a base substrate is provided and a first conductive layer is formed on the base substrate; then, a first insulating thin film and a semiconductor thin film are sequentially deposited on the base substrate formed with the aforementioned structure, and the semiconductor thin film is patterned through a patterning process to form a first insulating layer 11 and a semiconductor layer disposed on the first insulating layer 11; then, a first transparent conductive thin film is deposited on the base substrate 10 formed with the aforementioned structure, and the first transparent conductive thin film is patterned through a patterning process to form a first transparent conductive layer; after that, a second conductive thin film is deposited on the base substrate 10 formed with the aforementioned structure, and the second conductive thin film is patterned through a patterning process to form a second conductive layer; next, a third insulating thin film is deposited on the base substrate 10 formed with the aforementioned structure, and the third insulating thin film is patterned to form a third insulating layer 13; then, a second transparent conductive thin film is deposited, and the second transparent conductive thin film is patterned to form a second transparent conductive layer.

In some exemplary embodiments, the first insulating layer 11 and the third insulating layer 13 may be made of any one or more of silicon oxide (SiOx), silicon nitride (SiNx), and silicon oxynitride (SiON), and may be a single layer, a multi-layer, or a composite layer. The first conductive layer and the second conductive layer may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti. The first transparent conductive layer and the second transparent conductive layer may be made of a transparent conductive material, such as indium tin oxide (ITO) or indium zinc oxide (IZO). However, this embodiment is not limited to this.

According to a display substrate provided by this exemplary embodiment, two touch signal lines are arranged in each pixel unit, and the two touch signal lines are located on one side of a data line connected with one sub-pixel of a pixel unit, so that a situation where too many touch signal lines occupy a pixel aperture is avoided, thereby improving a transmittance and a display effect. Furthermore, a process of the display substrate provided by this embodiment is simple to achieve, easy to implement, and has a high production efficiency, a low production cost, and a high yield.

At least one embodiment of the present disclosure further provides a preparation method of an array substrate, which is used for preparing the array substrate as described above. The preparation method includes the following acts: forming a plurality of pixel units and a plurality of touch signal lines on a base substrate. At least one pixel unit includes a plurality of sub-pixels; two touch signal lines are arranged in the pixel unit, and the two touch signal lines are located on one side of a data line connected with one sub-pixel of the pixel unit.

In some exemplary embodiments, the forming the plurality of pixel units and the plurality of touch signal lines on the base substrate, includes: forming a first conductive layer on the base substrate, wherein the first conductive layer at least includes control electrodes of a plurality of switching elements and a plurality of gate lines; forming a semiconductor layer on a side of the first conductive layer away from the base substrate, wherein the semiconductor layer at least includes: active layers of a plurality of switching elements; forming a second conductive layer on a side of the semiconductor layer away from the base substrate, wherein the second conductive layer includes first and second electrodes of a plurality of switching elements, a plurality of data lines, and a plurality of touch signal lines; and forming sequentially a first transparent conductive layer and a second transparent conductive layer on a side of the second conductive layer away from the base substrate. The first transparent conductive layer includes a plurality of touch electrodes, and the second transparent conductive layer includes a plurality of pixel electrodes; or, the first transparent conductive layer includes a plurality of pixel electrodes, and the second transparent conductive layer includes a plurality of touch electrodes.

In some exemplary embodiments, the forming the plurality of pixel units and the plurality of touch signal lines on the base substrate, includes: forming a first conductive layer on the base substrate, wherein the first conductive layer at least includes control electrodes of a plurality of switching elements and a plurality of gate lines; forming a semiconductor layer on a side of the first conductive layer away from the base substrate, wherein the semiconductor layer at least includes: active layers of a plurality of switching elements; forming a first transparent conductive layer on a side of the semiconductor layer away from the base substrate, wherein the first transparent conductive layer at least includes a plurality of pixel electrodes; forming a second conductive layer on a side of the first transparent conductive layer away from the base substrate, wherein the second conductive layer includes first and second electrodes of a plurality of switching elements, a plurality of data lines, and a plurality of touch signal lines; forming a second transparent conductive layer on a side of the second conductive layer away from the base substrate, wherein the second transparent conductive layer at least includes a plurality of common electrodes.

For detailed description of the preparation method of this embodiment, reference may be made to the foregoing embodiment, so it will not be repeated here.

At least one embodiment of the present disclosure further provides a touch display apparatus, which includes the array substrate as described above.

In some exemplary embodiments, the touch display apparatus may include an array substrate, an opposite substrate, and a liquid crystal layer disposed between the array substrate and the opposite substrate. A pixel electrode and a common electrode (which is reused as a touch electrode) included in an array substrate are used for generating an electric field for controlling deflection of liquid crystal molecules in a liquid crystal layer. In some examples, the opposite substrate may include a base substrate, a black matrix and a color film layer that are disposed on the base substrate. However, this embodiment is not limited to this.

In some exemplary embodiments, a touch display apparatus may be any product or component with touch and display functions, such as a liquid crystal panel, electronic paper, a mobile phone, a tablet computer, a television, a display, a laptop computer, a digital photo frame, and a navigator.

The drawings in the present disclosure only refer to structures involved in the present disclosure, and other structures may refer to common designs. The embodiments of the present disclosure and features in the embodiments may be combined with each other to obtain a new embodiment if there is no conflict.

Those of ordinary skills in the art should understand that modifications or equivalent substitutions may be made to the technical solutions of the present disclosure without departing from the spirit and scope of the technical solutions of the present disclosure, all of which should be included within the scope of the claims of the present disclosure.

What is claimed is:

1. An array substrate, comprising:
a base substrate, a plurality of pixel units and a plurality of touch signal lines that are arranged on the base substrate;
wherein at least one pixel unit of the plurality of pixel units comprises a plurality of sub-pixels; two touch signal lines are arranged in the pixel unit, and the two touch signal lines are located on a side of a data line connected with one sub-pixel of the pixel unit.

2. The array substrate according to claim 1, wherein the pixel unit comprises a first sub-pixel, a second sub-pixel, and a third sub-pixel arranged sequentially; and the two touch signal lines arranged in the pixel unit are located on a side of a data line connected with the first sub-pixel of the pixel unit.

3. The array substrate according to claim 1, wherein the plurality of touch signal lines and a plurality of data lines are structures in a same layer, and the plurality of touch signal lines extend along an extension direction of the plurality of data lines.

4. The array substrate according to claim 1, wherein the array substrate further comprises a first transparent conductive layer and a second transparent conductive layer; and the second transparent conductive layer is located on a side of the first transparent conductive layer away from the base substrate;
the first transparent conductive layer comprises a plurality of common electrodes, and the second transparent conductive layer comprises a plurality of pixel electrodes; or, the first transparent conductive layer comprises a plurality of pixel electrodes, and the second transparent conductive layer comprises a plurality of common electrodes;
the common electrodes are reused as touch electrodes and connected with the touch signal lines.

5. The array substrate according to claim 4, wherein common electrodes of the plurality of sub-pixels of the pixel unit are of an integral structure, and common electrodes of adjacent pixel units are connected through a first connection unit.

6. The array substrate according to claim 4, wherein overlapping areas of pixel electrodes of the plurality of sub-pixels of the pixel unit and corresponding common electrodes are approximately the same.

7. The array substrate according to claim 4, wherein an orthographic projection of the common electrode on the base substrate covers an orthographic projection of the data line on the base substrate.

8. The array substrate according to claim 4, wherein orthographic projections of the common electrodes on the base substrate are not overlapped with orthographic projections of the touch signal lines on the base substrate.

9. The array substrate according to claim 4, wherein the first transparent conductive layer and the second transparent conductive layer are both located on a side of the plurality of touch signal lines away from the base substrate.

10. The array substrate according to claim 9, wherein in a plane perpendicular to the array substrate, the array substrate at least comprises the base substrate, and a first conductive layer, a semiconductor layer, a second conductive layer, a first transparent conductive layer, and a second transparent conductive layer that are arranged on the base substrate;
the first conductive layer at least comprises control electrodes of a plurality of switching elements and a plurality of gate lines;
the semiconductor layer at least comprises: active layers of a plurality of switching elements;
the second conductive layer at least comprises first and second electrodes of a plurality of switching elements, a plurality of data lines, and a plurality of touch signal lines;
an organic insulating layer is arranged between the second conductive layer and the first transparent conductive layer.

11. The array substrate according to claim 10, wherein at least one switching element is located at an intersection position of a data line and a gate line.

12. The array substrate according to claim 4, wherein the first transparent conductive layer is located on a side of the plurality of touch signal lines close to the base substrate, and the second transparent conductive layer is located on a side of the plurality of touch signal lines away from the base substrate; the first transparent conductive layer comprises a plurality of pixel electrodes, and the second transparent conductive layer comprises a plurality of common electrodes.

13. The array substrate according to claim 1, wherein the plurality of sub-pixels of the plurality of pixel units form a plurality of columns of sub-pixels; and the two touch signal lines are located on a side of sub-pixels of a corresponding column.

14. The array substrate according to claim 1, wherein the data line is connected with sub-pixels of a corresponding column through switching elements, and the two touch signal lines are located on a side of a corresponding data line away from switching elements connected to the corresponding data line.

15. A touch display apparatus comprising an array substrate, wherein the array substrate comprises: a base substrate, a plurality of pixel units and a plurality of touch signal lines that are arranged on the base substrate;
at least one pixel unit of the plurality of pixel units comprises a plurality of sub-pixels; two touch signal lines are arranged in the pixel unit, and the two touch signal lines are located on a side of a data line connected with one sub-pixel of the pixel unit.

16. The touch display apparatus according to claim 15, wherein the pixel unit comprises a first sub-pixel, a second sub-pixel, and a third sub-pixel arranged sequentially; and the two touch signal lines arranged in the pixel unit are located on a side of a data line connected with the first sub-pixel of the pixel unit.

17. The touch display apparatus according to claim 15, wherein a plurality of sub-pixels of a plurality of pixel units form a plurality of columns of sub-pixels; and the two touch signal lines are located on a side of sub-pixels of a corresponding column;
the data line is connected with sub-pixels of a corresponding column through switching elements, and the two touch signal lines are located on a side of a corresponding data line away from switching elements connected to the corresponding data line.

18. A preparation method of an array substrate, comprising:
forming a plurality of pixel units and a plurality of touch signal lines on a base substrate;
wherein, at least one pixel unit of the plurality of pixel units comprises a plurality of sub-pixels; two touch signal lines are arranged in the pixel unit, and the two touch signal lines are located on a side of a data line connected with one sub-pixel of the pixel unit.

19. The preparation method according to claim 18, wherein the forming the plurality of pixel units and the plurality of touch signal lines on the base substrate, comprises:
forming a first conductive layer on the base substrate, wherein the first conductive layer at least comprises control electrodes of a plurality of switching elements and a plurality of gate lines;
forming a semiconductor layer on a side of the first conductive layer away from the base substrate, wherein the semiconductor layer at least comprises active layers of a plurality of switching elements;
forming a second conductive layer on a side of the semiconductor layer away from the base substrate, wherein the second conductive layer comprises first and second electrodes of a plurality of switching elements, a plurality of data lines, and a plurality of touch signal lines; and
forming sequentially a first transparent conductive layer and a second transparent conductive layer on a side of the second conductive layer away from the base substrate;
wherein the first transparent conductive layer at least comprises a plurality of common electrodes, and the second transparent conductive layer at least comprises a plurality of pixel electrodes; or, the first transparent conductive layer at least comprises a plurality of pixel electrodes, and the second transparent conductive layer at least comprises a plurality of common electrodes.

20. The preparation method according to claim 18, wherein the forming the plurality of pixel units and the plurality of touch signal lines on the base substrate, comprises:
forming a first conductive layer on the base substrate, wherein the first conductive layer at least comprises control electrodes of a plurality of switching elements and a plurality of gate lines;
forming a semiconductor layer on a side of the first conductive layer away from the base substrate, wherein the semiconductor layer at least comprises active layers of a plurality of switching elements;
forming a first transparent conductive layer on a side of the semiconductor layer away from the base substrate, wherein the first transparent conductive layer at least comprises a plurality of pixel electrodes;
forming a second conductive layer on a side of the first transparent conductive layer away from the base substrate, wherein the second conductive layer comprises first and second electrodes of a plurality of switching elements, a plurality of data lines, and a plurality of touch signal lines; and
forming a second transparent conductive layer on a side of the second conductive layer away from the base substrate, wherein the second transparent conductive layer at least comprises a plurality of common electrodes.
